(19) United States
(12) Patent Application Publication
(10) Pub. No.: US 2025/0054866 A1
(43) Pub. Date: Feb. 13, 2025

(54) INTERCONNECT STRUCTURE AND ELECTRONIC DEVICE INCLUDING THE SAME

(71) Applicant: Samsung Electronics Co., Ltd., Suwon-si (KR)

(72) Inventors: Keun Wook SHIN, Suwon-si (KR); Sangwon KIM, Suwon-si (KR); Chang Seok LEE, Suwon-si (KR); Joonseok KIM, Suwon-si (KR); Joonyun KIM, Suwon-si (KR); Giyoung JO, Suwon-si (KR); Luhing HU, Suwon-si (KR)

(21) Appl. No.: 18/796,804

(22) Filed: Aug. 7, 2024

(30) Foreign Application Priority Data
Aug. 7, 2023 (KR) 10-2023-0103154

(51) Int. Cl. H01L 23/532; H01L 23/528

(52) U.S. Cl. CPC H01L 23/5329; H01L 23/5283; H01L 23/53219; H01L 23/53223; H01L 23/53233; H01L 23/53238; H01L 23/53247; H01L 23/53252; H01L 23/53261; H01L 23/53266

(57) ABSTRACT

Disclosed are an interconnect structure including a substrate, a metal layer on the substrate, and a passivation layer including a topological compound and in contact with the metal layer.

### CROSS-REFERENCE TO RELATED APPLICATION

This application claims priority to and the benefit of Korean Patent Application No. 10-2023-0103154 filed in the Korean Intellectual Property Office on Aug. 7, 2023, the content of which in its entirety is herein incorporated by reference.

### BACKGROUND

### 1. Field

The present disclosure relates to an interconnect structure and an electronic device including the same.

### 2. Description of the Related Art

In order to provide high-density, high-performance semiconductor devices, efforts are continuing to reduce the line width or thickness of metal wiring. By reducing the line width or thinning the thickness of metal wiring, the number of semiconductor chips integrated per wafer can be increased. Additionally, when the thickness of the metal wiring is thinned, the capacitance of the line can be reduced, and thus the speed of the signal passing through the wiring can be increased.

However, as the line width or thickness of the metal wiring decreases, the resistance increases rapidly, and thus reducing the resistance of the metal wiring becomes more important than anything else. Current wiring technology is approaching its physical limits where resistivity increases significantly as line width decreases significantly.

Additionally, since deterioration may occur due to oxidation occurring at the metal/oxide interface or exposed metal surface, a technology is needed to reduce the resistance of the wiring structure while preventing metal oxidation.

### SUMMARY

An embodiment provides an interconnect structure that can prevent oxidation of metal wiring while reducing an increase in resistance due to a decrease in line width of the metal wiring.

An embodiment provides an electronic device including the interconnect structure.

According to an embodiment, an interconnect structure includes a substrate, a metal layer on the substrate, and a passivation layer including a topological compound and in contact with the metal layer.

The passivation layer may be disposed on an upper surface, a bottom surface, or both of the metal layer.

The metal layer may include metal, a metal alloy, or a combination thereof.

The metal may include a transition metal, a Group 13 metal, or a combination thereof.

The metal layer may include a metal selected from copper (Cu), ruthenium (Ru), aluminum (Al), cobalt (Co), tungsten (W), molybdenum (Mo), titanium (Ti), tantalum (Ta), nickel (Ni), platinum (Pt), chromium (Cr), rhodium (Rh), iridium (Ir), palladium (Pd), or osmium (Os), an alloy thereof, or a combination thereof.

The passivation layer may include a topological compound represented by Chemical Formula 1.

M_{y}X [Chemical Formula 1]

In Chemical Formula 1, M may be copper (Cu), ruthenium (Ru), aluminum (Al), cobalt (Co), tungsten (W), molybdenum (Mo), titanium (Ti), tantalum (Ta), nickel (Ni), platinum (Pt), chromium (Cr), rhodium (Rh), iridium (Ir), palladium (Pd), osmium (Os), or a combination thereof, X may be phosphorus (P), arsenic (As), antimony (Sb), sulfur(S), selenium (Se), tellurium (Te), or a combination thereof, and 0<y≤10.

The topological compound may have a hexagonal close packed (HCP) lattice structure.

The metal layer may have a thickness of greater than or equal to about 0.1 nanometers (nm) and less than or equal to about 10 nm, and the passivation layer may have a thickness of greater than or equal to about 0.1 nm and less than or equal to about 10 nm.

A thickness ratio of the metal layer and the passivation layer may range from about 1:0.01 to about 1:2.

The interconnect structure may further include a barrier layer between the substrate and the metal layer or between the substrate and the passivation layer.

The substrate may include a dielectric layer defining a trench structure therein, the metal layer may fill the inside of the trench structure, and the passivation layer may be located on an upper surface of the metal layer.

The substrate may include a dielectric layer defining a trench structure therein, the metal layer may fill the inside of the trench structure, and the passivation layer may be located on a lower surface and side surfaces of the metal layer.

The substrate may include a dielectric layer defining a trench structure therein, the metal layer may fill the inside of the trench structure, and the passivation layer may surround entire surfaces of the metal layer.

The interconnect structure may further include a barrier layer on at least one inner surface of the trench structure.

The barrier layer may include a metal, a metal alloy, metal oxide, metal nitride, or a combination thereof.

The metal of the barrier layer may include magnesium (Mg), aluminum (Al), scandium (Sc), titanium (Ti), vanadium (V), chromium (Cr), manganese (Mn), nickel (Ni), and zinc (Zn), gallium (Ga), zirconium (Zr), niobium (Nb), molybdenum (Mo), lead (Pd), silver (Ag), cadmium (Cd), indium (In), tin (Sn), lanthanum (La), hafnium (Hf), tantalum (Ta), tungsten (W), iridium (Ir), platinum (Pt), gold (Au), bismuth (Bi), cobalt (Co), ruthenium (Ru), or a combination thereof. The metal alloy of the barrier layer may include ruthenium tantalum (RuTa), iridium tantalum (IrTa), and/or the like.

The metal oxide of the barrier layer may be a compound represented by Chemical Formula 2.

MₓO_{y} [Chemical Formula 2]

In Chemical Formula 2,

M may be one or more selected from Mn, Al, Ti, Zr, Hf, Mg, silicon (Si), germanium (Ge), yttrium (Y), lutetium (Lu), La, Ta, and strontium (Sr), 0<x≤2, and 0<y≤3.

Examples of the metal oxides may include MnO, AlO_{z} (0<z≤3/2), TaO_{z}, (0<z≤5/2), TiO₂, ZrO₂, HfO₂, MgO, SiO₂, GeO₂, Y₂O₃, Lu₂O₃, La₂O₃, SrO, and the like.

The metal nitride of the barrier layer may include tantalum nitride (TaN), titanium nitride (TiN), ruthenium nitride (RuN), tungsten nitride (WN), aluminum nitride (AlN), iridium tantalum nitride (IrTaN), titanium silicon nitride (TiSiN), and/or the like.

Another embodiment provides an electronic device including the interconnect structure.

The electronic device may be a transistor, a capacitor, a diode, or a resistor.

The interconnect structure can prevent oxidation of the metal wiring while reducing an increase in resistance due to a decrease in the line width of the metal wiring.

### BRIEF DESCRIPTION OF THE DRAWINGS

FIGS. 1 to 3 are cross-sectional views of interconnect structures according to some example embodiments.

FIGS. 4 to 9 are cross-sectional views of interconnect structures according to some example embodiments.

FIG. 10 is a cross-sectional view of an interconnect structure according to an embodiment.

FIGS. 11 and 12 are cross-sectional views of electronic devices according to some example embodiments.

### DETAILED DESCRIPTION

Hereinafter, example embodiments of the present disclosure will be described in detail so that a person skilled in the art would understand the same. This disclosure may, however, be embodied in many different forms and is not construed as limited to the example embodiments set forth herein.

The terminology used herein is used to describe embodiments only, and is not intended to limit the present disclosure. The singular expression includes the plural expression unless the context clearly dictates otherwise.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer, or section from another element, component, region, layer, or section. Thus, “a first element,” “component,” “region,” “layer,” or “section” discussed below could be termed a second element, component, region, layer, or section without departing from the teachings herein. The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. “At least one” is not to be construed as limiting “a” or “an.” “Or” means “and/or.” As used herein, the term “and/or” includes any and all combinations of one or more of the associated listed items.

As used herein, terms such as “comprise,” “comprise,” or “have” are intended to designate the presence of implemented features, numbers, steps, components, or a combination thereof, but not one or more other features, numbers, steps, components, or combinations thereof should be understood as not excluding in advance the existence or possibility of addition.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. In contrast, when an element is referred to as being “directly on” another element, there are no intervening elements present.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, ±5%, ±3%, or ±1% of the stated value.

Relative terms, such as “downward,” “lower,” or “bottom,” and “upward,” “upper,” or “top,” may be used herein to describe one element's relationship to another element as illustrated in the drawings. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Example embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In addition, “layer” herein includes not only a shape formed on the whole surface when viewed from a plan view, but also a shape formed on a partial surface.

The use of the term “the” and similar referential terms may refer to both the singular and the plural. Unless the order of the steps constituting the method is clearly stated or stated to the contrary, these steps may be performed in any appropriate order and are not necessarily limited to the order described.

In addition, terms such as “ . . . unit” and “module” used in the specification refer to a unit that processes at least one function or operation, which may be implemented as hardware or software, or as a combination of hardware and software.

The connections or connection members of lines between components shown in the drawings exemplify functional connections and/or physical or circuit connections, and in actual devices, may be represented as various functional connections, physical connections, or circuit connections.

As used herein, “at least one of A, B or C,” “one of A, B, C, or a combination thereof” and “one of A, B, C, and a combination thereof” refer to each component and refers to any combination (e.g., A; B; C; A and B; A and C; B and C; or A, B, and C).

Herein, “a combination thereof” means a mixture of components, a laminate, a composite, an alloy, a blend, and/or the like.

Herein, “metal” is interpreted as a concept that includes metals and metalloids (semimetals).

Hereinafter, an interconnect structure according to an embodiment will be described with reference to the attached drawings.

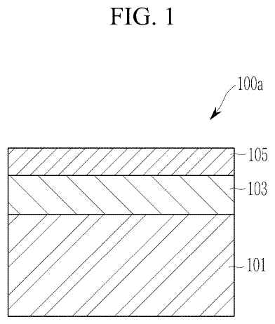

FIGS. 1 to 3 are cross-sectional views of interconnect structures according to some example embodiments.

Referring to FIGS. 1 to 3, the interconnect structures 100a, 100b, and 100c includes a substrate 101, a metal layer 103 on the substrate 101, and a passivation layer 105. The passivation layer 105 is in contact with the metal layer 103 and includes a topological compound.

The passivation layer 105 may be disposed on an upper surface, a bottom surface, or both of the metal layer 103.

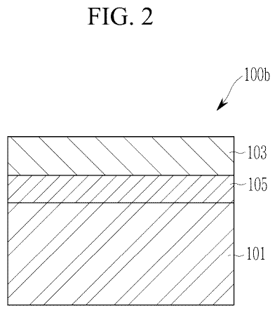

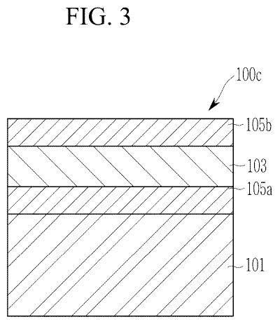

FIG. 1 shows a structure in which the passivation layer 105 is located on the upper surface of the metal layer 103, FIG. 2 shows a structure in which the passivation layer 105 is formed on the lower surface of the metal layer 103, that is, between the substrate 101 and the metal layer 103, and FIG. 3 shows a structure in which the passivation layer 105 is formed on both the upper and lower surfaces of the metal layer 103.

The substrate 101 may include at least one of a Group IV semiconductor material, a semiconductor compound (e.g., a Group III-V compound semiconductor, or a Group II-VI compound semiconductor), an insulator, or a metal. For example, the substrate may include a Group IV semiconductor material such as Si, Ge, or Sn. Or, for example, the substrate may include at least one of Si, Ge, C, Zn, Cd, Al, Ga, In, B, C, N, P, S, Se, As, Sb, Te Ta, Ru, Rh, Ir, Co, Ta, Ti, W, Pt, Au, Ni, or Fe. For example, the substrate may include Si, Ge, SiC, SiGe, SiGeC, Ge alloy, GaAs, InAs, InP, etc. The substrate may include a single layer or multiple layers of different materials stacked.

For example, the substrate 101 may include a Silicon-On-Insulator (SOI) substrate or a Silicon Germanium-On-Insulator (SGOI) substrate. For example, the substrate may further include N and F in a SiCOH-based composition, and may also include pores to lower the dielectric constant. Meanwhile, the substrate 101 may further include a dopant.

The metal layer 103 may include a metal, a metal alloy, or a combination thereof.

The metal layer 103 may include a metal selected from copper (Cu), ruthenium (Ru), aluminum (Al), cobalt (Co), tungsten (W), molybdenum (Mo), titanium (Ti), tantalum (Ta), nickel (Ni), platinum (Pt), chromium (Cr), rhodium (Rh), iridium (Ir), palladium (Pd), or osmium (Os), an alloy thereof, or a combination thereof.

The passivation layer 105 may include a compound represented by Chemical Formula 1.

M_{y}X [Chemical Formula 1]

In Chemical Formula 1, M may be copper (Cu), ruthenium (Ru), aluminum (Al), cobalt (Co), tungsten (W), molybdenum (Mo), titanium (Ti), tantalum (Ta), nickel (Ni), platinum (Pt), chromium (Cr), rhodium (Rh), iridium (Ir), palladium (Pd), osmium (Os), or a combination thereof, X may be phosphorus (P), arsenic (As), antimony (Sb), sulfur(S), selenium (Se), tellurium (Te), or a combination thereof, and y may be in the range of less than or equal to 10.

The topological compound may have a hexagonal close packed (HCP) lattice structure.

The topological compound may be a single crystalline or polycrystalline compound.

The metal layer 103 may have a thickness of less than or equal to about 10 nanometers (nm), for example less than or equal to about 9 nm, less than or equal to about 8 nm, less than or equal to about 7 nm, less than or equal to about 6 nm, and greater than or equal to about 0.1 nm. Within the above range, it is possible to provide a nanoscale wiring structure. The passivation layer may have a thickness of less than or equal to about 10 nm, for example less than or equal to about 9 nm, less than or equal to about 8 nm, less than or equal to about 7 nm, less than or equal to about 6 nm, and greater than or equal to about 0.1 nm. Within the above range, oxidation of the metal layer 103 can be prevented, a rapid increase in resistance can be prevented, and topological properties can be exhibited.

The thickness ratio of the metal layer 103 and the passivation layer 105 may be in the range of about 1:0.01 to about 1:2. The ratio of the thickness of the passivation layer 105 to the metal layer 103 may be, for example, greater than or equal to about 0.02, greater than or equal to about 0.03, greater than or equal to about 0.04, greater than or equal to about 0.05, greater than or equal to about 0.06, greater than or equal to about 0.07, greater than or equal to about 0.08, greater than or equal to about 0.09, greater than or equal to about 0.1, greater than or equal to about 0.2, greater than or equal to about 0.3, greater than or equal to about 0.4, or greater than or equal to about 0.5, and may be less than or equal to about 1.9, less than or equal to about 1.7, less than or equal to about 1.6, less than or equal to about 1.5, less than or equal to about 1.4, less than or equal to about 1.3, less than or equal to about 1.2, less than or equal to about 1.1, less than about 1, or less than or equal to about 1. Additionally, the ratio of the thickness of the passivation layer 105 to the metal layer 103 may be within a range combining the above numerical ranges.

The conductive wiring configured to have a heterogeneous structure of the metal layer 103 and the passivation layer 105 can prevent an increase in electrical resistance due to a decrease in the wiring line width and reduce or prevent defects in the wiring due to electromigration. The passivation layer 105 may serve as a barrier layer to prevent the material of the metal layer 103 from diffusing.

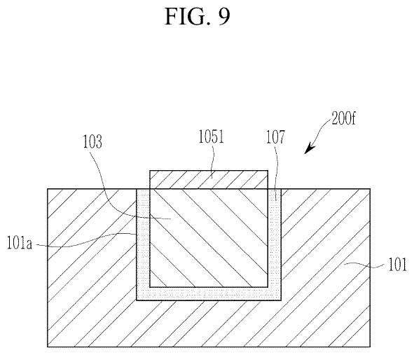

A barrier layer (See FIG. 9) may be further included between the substrate 101 and the metal layer 103 or between the substrate 101 and the passivation layer 105.

The barrier layer may include a metal, a metal alloy, metal oxide, metal nitride, or a combination thereof.

The barrier layer can prevent the materials of the metal layer 103 and the passivation layer 105 from diffusing into the substrate 101. The barrier layer may have a multilayered structure in which a plurality of layers including different materials are stacked. For example, the barrier layer may include a first barrier layer in contact with the metal layer 103 or the passivation layer 105 and a second barrier layer in contact with the substrate 101, and the first barrier layer may include a metal or a metal alloy and the second barrier layer may include metal nitride or metal oxide.

The metal that is usable in the barrier layer may include magnesium (Mg), aluminum (Al), scandium (Sc), titanium (Ti), vanadium (V), chromium (Cr), manganese (Mn), nickel (Ni), and zinc (Zn), gallium (Ga), zirconium (Zr), niobium (Nb), molybdenum (Mo), lead (Pd), silver (Ag), cadmium (Cd), indium (In), tin (Sn), lanthanum (La), hafnium (Hf), tantalum (Ta), tungsten (W), iridium (Ir), platinum (Pt), gold (Au), bismuth (Bi), cobalt (Co), ruthenium (Ru), or a combination thereof. The metal alloy of the barrier layer may include RuTa, IrTa, etc.

The metal oxide of the barrier layer may be a compound represented by Chemical Formula 2.

MₓO_{y} [Chemical Formula 2]

In Chemical Formula 2,

M may be one or more selected from Mn, Al, Ti, Zr, Hf, Mg, Si, Ge, Y, Lu, La, Ta, and Sr, 0<x≤2, and 0<y≤3.

Examples of the metal oxide may include MnO, AlO_{z} (0<z≤3/2), TaO_{z}, (0<z≤5/2), TiO₂, ZrO₂, HfO₂, MgO, SiO₂, GeO₂, Y₂O₃, Lu₂O₃, La₂O₃, SrO, and the like.

The metal nitride of the barrier layer may include tantalum nitride (TaN), titanium nitride (TiN), ruthenium nitride (RUN), tungsten nitride (WN), aluminum nitride (AlN), IrTaN, TiSiN, and/or the like.

A multilayered metal wiring structure including the metal layer 103 and the passivation layer 105 may be disposed in the trench of the substrate 101.

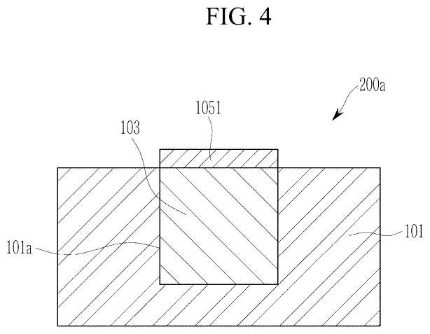

This structure is explained with reference to FIGS. 4 to 8. FIGS. 4 to 8 are cross-sectional views of interconnect structures according to some example embodiments.

Referring to FIG. 4, the interconnect structure 200a includes a metal layer 103 filled inside the trench 101a of the substrate 101 and a passivation layer 1051 on the upper surface of the metal layer 103.

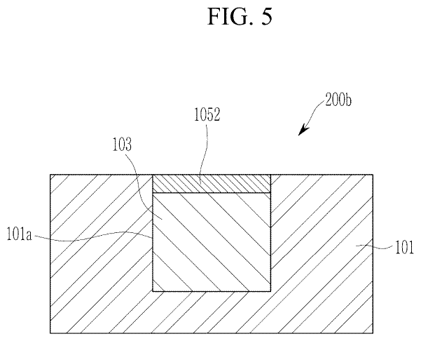

Referring to FIG. 5, the interconnect structure 200b includes a metal layer 103 and a passivation layer 1052 on the upper surface of the metal layer 103, inside the trench 101a of the substrate 101.

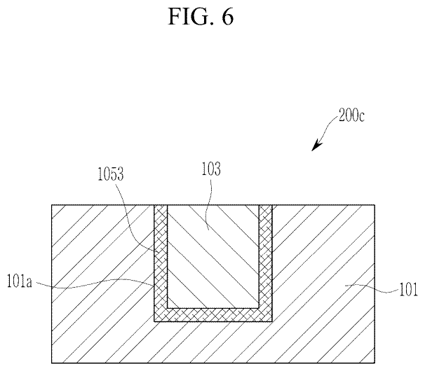

Referring to FIG. 6, the interconnect structure 200c includes a passivation layer 1053 located along the trench 101a inside the trench 101a of the substrate 101, and a metal layer 103 inside the trench 101a.

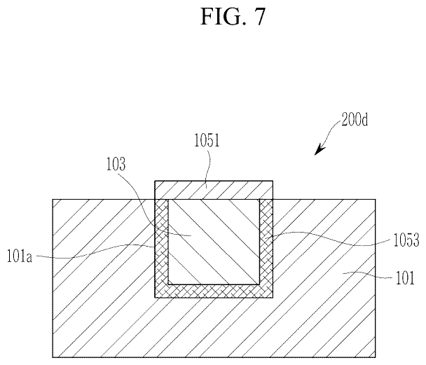

Referring to FIG. 7, the interconnect structure 200d includes a first passivation layer 1053 located along the trench 101a inside the trench 101a of the substrate 101, a metal layer 103 filled therein, and a second passivation layer 1051 located on the upper surface of the metal layer 103.

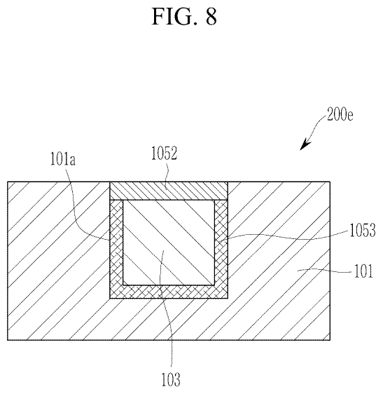

Referring to FIG. 8, the interconnect structure 200e includes a first passivation layer 1053 located along the trench 101a inside the trench 101a of the substrate 101, a metal layer 103 filled therein, and a second passivation layer 1052 located on the metal layer 103 and the first passivation layer 1053.

A photolithography process or an etching process such as reactive ion etching (RIE) may be used as a method of forming the trench of the substrate 101.

In FIGS. 5 to 8, the substrate 101, metal layer 103, and passivation layers 1051, 1052, and 1053 have the same configuration as those described in FIGS. 1 to 3, and thus their detailed descriptions are omitted.

In the interconnect structures shown in FIGS. 5 to 8, a barrier layer may be located on the inner surface of the trench 101a. FIG. 9 shows a structure in which a barrier layer is additionally included in the interconnect structure of FIG. 4. FIG. 9 is a cross-sectional view of an interconnect structure according to an embodiment.

Referring to FIG. 9, the interconnect structure 200f includes a barrier layer 107 located on both side surfaces and the lower surface of the trench 101a of the substrate 101, and the barrier layer 107 is configured to surround the metal layer 103 located inside the trench 101a, and the passivation layer 1051 is located on the upper surface of the metal layer 103.

The barrier layer 107 can prevent the materials of the metal layer 103 and the passivation layer 105 from diffusing into the substrate 101. The barrier layer 107 may have a multilayered structure in which a plurality of layers including different materials are stacked. For example, the barrier layer 107 may include a first barrier layer in contact with the metal layer 103 or the passivation layer 105 and a second barrier layer in contact with the substrate 101, and the first barrier layer may include a metal or a metal alloy, and the second barrier layer may include a metal nitride or a metal oxide.

The metal that is usable in the barrier layer may include magnesium (Mg), aluminum (Al), scandium (Sc), titanium (Ti), vanadium (V), chromium (Cr), manganese (Mn), nickel (Ni), and zinc (Zn), gallium (Ga), zirconium (Zr), niobium (Nb), molybdenum (Mo), lead (Pd), silver (Ag), cadmium (Cd), indium (In), tin (Sn), lanthanum (La), hafnium (Hf), tantalum (Ta), tungsten (W), iridium (Ir), platinum (Pt), gold (Au), bismuth (Bi), cobalt (Co), ruthenium (Ru), or a combination thereof. The metal alloy of the barrier layer may include RuTa, IrTa, and/or the like.

The metal oxide of the barrier layer may be a compound represented by Chemical Formula 2.

MₓO_{y} [Chemical Formula 2]

In Chemical Formula 2,

M may be one or more selected from Mn, Al, Ti, Zr, Hf, Mg, Si, Ge, Y, Lu, La, Ta, and Sr, 0<x≤2, and 0<y≤3.

Examples of the metal oxides may include MnO, AlO_{z} (0<z≤3/2), TaO_{z}, (0<z≤5/2), TiO₂, ZrO₂, HfO₂, MgO, SiO₂, GeO₂, Y₂O₃, Lu₂O₃, La₂O₃, SrO, and the like.

The metal nitride of the barrier layer may include tantalum nitride (TaN), titanium nitride (TiN), ruthenium nitride (RUN), tungsten nitride (WN), aluminum nitride (AlN), IrTaN, TiSiN, and/or the like.

Although an example in which a barrier layer is formed in the structure of FIG. 4 has been described above, a barrier layer may also be provided along the trench 101a of the substrate 101 in the interconnect structure shown in FIGS. 5 to 8.

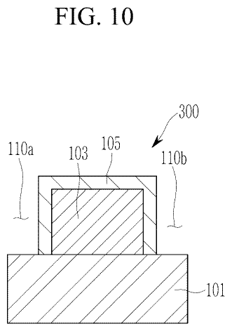

If the upper surface is a flat substrate, the multilayered wiring structure of the metal layer and the passivation layer may have empty spaces on both sides. This structure is shown in FIG. 10. FIG. 10 is a cross-sectional view of an interconnect structure according to an embodiment.

Referring to FIG. 10, the interconnect structure 300 has a multilayered structure of a metal layer 103 and a passivation layer 105 surrounding the metal layer 103 on a substrate 101, and empty spaces 110a and 110b are formed on opposite sides of the multilayered structure. These empty spaces 110a and 110b may be filled with air, etc., and if the empty spaces 110a and 110b are air gaps filled with air, the air gap itself may serve as a dielectric. FIG. 10 shows a structure in which the upper surface and side surfaces of the metal layer 103 are surrounded by a passivation layer 105, but a passivation layer may also exist on the lower surface of the metal layer 103. Additionally, a passivation layer may be present on any one of the upper surface, side surfaces, and bottom surface of the metal layer 103.

The aforementioned interconnect structure can alleviate an increase in electrical resistance due to a decrease in the line width of wiring due to high integration of semiconductor devices and can reduce or prevent defects caused by electromigration due to an increase in electrical resistance within the interconnect structure.

The metal layer and passivation layer of the interconnect structure can be formed by atomic layer deposition (ALD), chemical vapor deposition (CVD), or plasma enhanced CVD (PECVD), but the present disclosure is not limited thereto.

The aforementioned interconnect structures 100a, 100b, 100c, 200a, 200b, 200c, 200d, and 300 may provide electronic devices. For example, the electronic device may include a semiconductor device, in which case the interconnect structures 100a, 100b, 100c, 200a, 200b, 200c, 200d, and 300 may be applied to BEOL (Back End of Line) structure of the semiconductor device. The semiconductor device may include at least one of a transistor, a capacitor, a diode, or a resistor. In addition, the interconnect structures 100a, 100b, 100c, 200a, 200b, 200c, 200d, and 300 can be applied to various electronic devices.

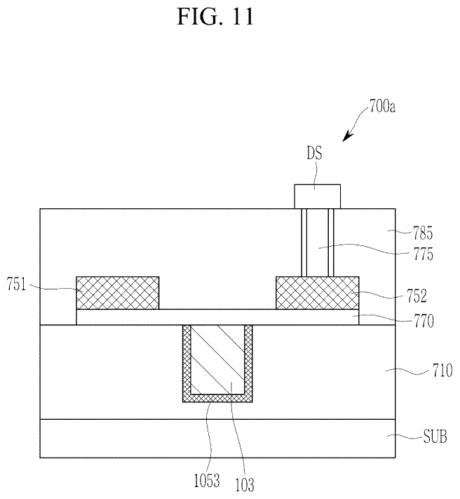

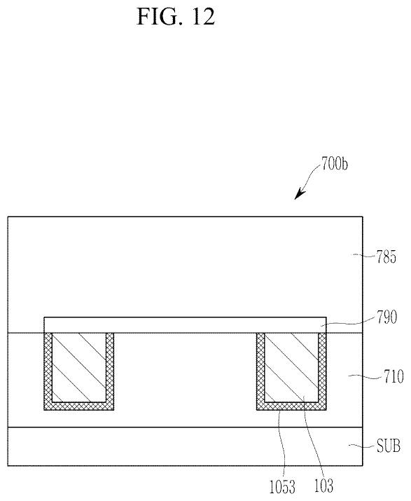

Hereinafter, an electronic device including the aforementioned interconnect structures will be described with reference to FIGS. 11 and 12.

FIGS. 11 and 12 are cross-sectional views of electronic devices according to some example embodiments.

Referring to FIG. 11, in an embodiment, the electronic device 700a may be formed of a transistor connected to data storage DS. The electronic device 700a may include a substrate SUB and an oxide dielectric layer 710. A metal layer 103 and a passivation layer 1053 are present inside the trench of the oxide dielectric layer 710. The metal layer 103 and the passivation layer 1053 are formed in the same structure as shown in FIG. 6. The metal layer and passivation layer of FIG. 11 may be arranged in any one of the structures shown in FIGS. 4, 5, and 7 to 9.

The gate insulating layer 770 is formed on the oxide dielectric layer 710. On the gate insulating layer 770, the source electrode 751 and the drain electrode 752 are arranged to be spaced apart from each other. The metal layer 103 may be configured to operate as a gate electrode of the electronic device 770a.

The electronic device 700a may further include an insulating layer 785, such as silicon oxide, covering the source electrode 751, the gate insulating layer 770, and the drain electrode 752, and a data storage (DS) (e.g., a capacitor) may be on the insulating layer 785. Contact 775 including an electrically conductive material such as a metal or a metal alloy may connect data storage DS and drain electrode 752.

Referring to FIG. 12, in an embodiment, the electronic device 700b different from the electronic device 700a shown in FIG. 11 in that the gate insulating layer 770, the contact 775, the source electrode 751, the drain electrode 752, and the data storage DS are omitted. Additionally, the oxide dielectric layer 710 includes two trenches spaced apart from each other, and each of the trenches is formed in the same structure as the interconnect structure in FIG. 6. That is, each of the trenches may include a metal layer 103 and a passivation layer 1053 formed therein.

A conductive layer 790 is formed on the oxide dielectric layer 710 and contacts the upper surface of the metal layer 103 in each interconnect structure, so that the interconnect structures can be electrically connected to each other. The conductive layer 790 may include a conductive material such as a metal, a metal alloy, or a doped semiconductor. The metal layer and passivation layer of FIG. 12 may be arranged in any one of the structures shown in FIGS. 4, 5, and 7 to 9.

While this disclosure has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

<Description of symbols>

| | |
|---|---|
| 100a, 100b, 100c, 200a, 200b, 200c, | |
| 200d, 300: interconnect structure | |
| 101, SUB: substrate | 103: metal layer |
| 105, 105a, 105b, 1051, 1052, 1053: | |
| passivation layer | |
| 700a, 700b: electronic device | 710: oxide dielectric |
| | material layer |
| 770: gate insulating layer | 751: source electrode |
| 752: drain electrode | DS: data storage |

What is claimed is:

1. An interconnect structure, comprising
a substrate;
a metal layer on the substrate; and
a passivation layer comprising a topological compound and in contact with the metal layer.

2. The interconnect structure of claim 1, wherein
the passivation layer is disposed on an upper surface, a bottom surface, or both of the metal layer.

3. The interconnect structure of claim 1, wherein
the metal layer comprises a metal, a metal alloy, or a combination thereof.

4. The interconnect structure of claim 3, wherein
the metal comprises a transition metal, a Group 13 metal, or a combination thereof.

5. The interconnect structure of claim 1, wherein
the metal layer comprises a metal selected from copper (Cu), ruthenium (Ru), aluminum (Al), cobalt (Co), tungsten (W), molybdenum (Mo), titanium (Ti), tantalum (Ta), nickel (Ni), platinum (Pt), chromium (Cr), rhodium (Rh), iridium (Ir), palladium (Pd), or osmium (Os), an alloy thereof, or a combination thereof.

6. The interconnect structure of claim 1, wherein
the passivation layer comprises a compound represented by Chemical Formula 1:
M_{y}X, [Chemical Formula 1]
wherein, in Chemical Formula 1, M is copper (Cu), ruthenium (Ru), aluminum (Al), cobalt (Co), tungsten (W), molybdenum (Mo), titanium (Ti), tantalum (Ta), nickel (Ni), platinum (Pt), chromium (Cr), rhodium (Rh), iridium (Ir), palladium (Pd), osmium (Os), or a combination thereof, X is phosphorus (P), arsenic (As), antimony (Sb), sulfur(S), selenium (Se), tellurium (Te), or a combination thereof, and 0<y≤10.

7. The interconnect structure of claim 1, wherein
the topological compound has a hexagonal close packed (HCP) lattice structure.

8. The interconnect structure of claim 1, wherein
the metal layer has a thickness of greater than or equal to about 0.1 nanometers (nm) and less than or equal to about 10 nm, and the passivation layer has a thickness of greater than or equal to about 0.1 nm and less than or equal to about 10 nm.

9. The interconnect structure of claim 1, wherein
a thickness ratio of the metal layer and the passivation layer ranges from about 1:0.01 to about 1:2.

10. The interconnect structure of claim 1, further comprising:
a barrier layer between the substrate and the metal layer or between the substrate and the passivation layer.

11. The interconnect structure of claim 1, wherein
the substrate comprises a dielectric layer defining a trench structure therein,
the metal layer fills an inside of the trench structure, and
the passivation layer is located on an upper surface of the metal layer.

12. The interconnect structure of claim 1, wherein
the substrate comprises a dielectric layer defining a trench structure therein,
the metal layer fills an inside of the trench structure, and
the passivation layer is located on a lower surface and side surfaces of the metal layer.

13. The interconnect structure of claim 1, wherein
the substrate comprises a dielectric layer defining a trench structure therein,
the metal layer fills an inside of the trench structure, and
the passivation layer surrounds entire surfaces of the metal layer.

14. The interconnect structure of claim 1, further comprising:
a barrier layer on at least one inner surface of the trench structure.

15. The interconnect structure of claim 14, wherein
the barrier layer comprises a metal, a metal alloy, metal oxide, metal nitride, or a combination thereof.

16. The interconnect structure of claim 15, wherein
the metal of the barrier layer is selected from magnesium (Mg), aluminum (Al), scandium (Sc), titanium (Ti), vanadium (V), chromium (Cr), manganese (Mn), nickel (Ni), and zinc (Zn), gallium (Ga), zirconium (Zr), niobium (Nb), molybdenum (Mo), lead (Pd), silver (Ag), cadmium (Cd), indium (In), tin (Sn), lanthanum (La), hafnium (Hf), tantalum (Ta), tungsten (W), iridium (Ir), platinum (Pt), gold (Au), bismuth (Bi), cobalt (Co), ruthenium (Ru), or a combination thereof.

17. The interconnect structure of claim 15, wherein
the metal oxide of the barrier layer is a compound represented by Chemical Formula 2:
MₓO_{y}, [Chemical Formula 2]
wherein, in Chemical Formula 2,
M is one or more selected from Mn, Al, Ti, Zr, Hf, Mg, silicon (Si), germanium (Ge), yttrium (Y), lutetium (Lu), La, Ta, and strontium (Sr), 0<x≤2, and 0<y≤3.

18. The interconnect structure of claim 15, wherein
the metal nitride of the barrier layer comprises tantalum nitride (TaN), titanium nitride (TiN), ruthenium nitride (RUN), tungsten nitride (WN), aluminum nitride (AlN), iridium tantalum nitride (IrTaN), titanium silicon nitride (TiSiN), or a combination thereof.

19. An electronic device comprising the interconnect structure of claim 1.

20. The electronic device of claim 19, wherein
the electronic device comprises a transistor, a capacitor, a diode, or a resistor.
